(19) United States
(12) Patent Application Publication
(10) Pub. No.: US 2010/0142162 A1
(43) Pub. Date: Jun. 10, 2010

(54) SWITCH DEVICE

(75) Inventors: Takayuki Adachi, Aichi (JP); Takashi Nagao, Aichi (JP)

Correspondence Address: ROBERTS MLOTKOWSKI SAFRAN & COLE, P.C.;Intellectual Property Department, P.O. Box 10064, MCLEAN, VA, 22102-8064, US

(73) Assignee: KABUSHIKI KAISHA TOKAI RIKA DENKI SEISAKUSHO, Aichi (JP)

(21) Appl. No.: 12/619,103

(22) Filed: Nov. 16, 2009

(30) Foreign Application Priority Data
Dec. 9, 2008 (JP) 2008-313319

(51) Int. Cl. H05K 5/00; H01H 21/00

(52) U.S. Cl. 361/752; 200/7

(57) ABSTRACT

A switch device for vehicle outer mirror includes a control board that mounts a control element for electrically controlling an outer mirror driver portion, a driver board that is separated from the control board and mounts a drive element for driving the outer mirror driver portion based on a control signal from the control board, and a housing for housing therein the control board and the driver board that are electrically connected by a coupling means.

The present application is based on Japanese Patent Application No. 2008-313319 filed on Dec. 9, 2008, the entire contents of which are incorporated herein by reference.

### BACKGROUND OF THE INVENTION

1. Field of the Invention

The present invention relates to a switch device for vehicle outer mirror.

2. Related Art

A conventional vehicle outer mirror device includes, e.g., a right outer mirror provided on a right side of a vehicle (e.g., on driver side) and a left outer mirror provided on a left side of the vehicle (e.g., on passenger side) for visually checking the rear of the vehicle (see JP-A 2002-100254). A right outer mirror driver portion is provided in the right outer mirror and a right side motor is included therein as a drive portion. Meanwhile, a left outer mirror driver portion is provided in the left outer mirror and a left side motor is included therein as a drive portion.

A switch device for vehicle outer mirror is provided inside the vehicle, and when the On/OFF operation of the switch device is carried out, the right and left side motors are driven by a current supplied thereto, and the right and left outer mirrors are housed, opened or angle-adjusted.

According to the switch device for vehicle outer mirror described in JP-A 2002-100254, it is possible to house, to open or to angle-adjust the outer mirror by operating an operation button of the switch device mounted on an instrument panel inside the vehicle.

However, according to the switch device for vehicle outer mirror described in JP-A 2002-100254, a circuit board that mounts a contact portion of the operation button and a control element and a drive element for controlling and driving the outer mirror driver portion needs to be housed in the switch device, and thus, the switch device becomes large. In addition, when the above-mentioned circuit board that mounts the control element and the drive element is mounted outside of the switch device, e.g., inside a door or an instrument panel, there is a problem that it competes with a circuit board of another on-vehicle equipment, in addition, it leads to the increase in the number of the assembly processes.

### SUMMARY OF THE INVENTION

Therefore, it is an object of the invention to provide a compact switch device for vehicle outer mirror configured to house therein a circuit board that mounts control and drive elements of the vehicle outer mirror.

(1) According to one embodiment of the present invention, a switch device for vehicle outer mirror comprises:

a control board that mounts a control element for electrically controlling an outer mirror driver portion;

a driver board that mounts a drive element for driving the outer mirror driver portion based on a control signal from the control board; and

a housing for housing therein the control board and the driver board that are electrically connected by a coupling means.

In the above embodiment (1), the following modifications and changes can be made.

(i) The coupling means is a connector.

(ii) The control board comprises a contact portion of a switch element for inputting a signal thereto.

(iii) The housing is arranged on a back side of the switch device.

(iv) The control board is arranged substantially parallel to the driver board.

(v) The control board and the driver board are arranged substantially parallel to a front face of the switch device.

(vi) The control board and the driver board are arranged substantially perpendicular to a front face of the switch device.

(vii) The control board and the driver board compose an ECU that is necessary for controlling and driving an outer mirror.

### Points of the Invention

According to one embodiment of the invention, a switch device for vehicle outer mirror is constructed such that an ECU for controlling and driving the outer mirror is divided into a control board and a driver board. Therefore, the switch device for vehicle outer mirror can be downsized and the ECU can be easy installed inside (or behind) the mirror switch panel so as not to mount a circuit board (including the control board and/or the driver board) inside a door or an instrument panel to provide improvement in assembly and reduction in the number of parts management processes.

### BRIEF DESCRIPTION OF THE DRAWINGS

Next, the present invention will be explained in more detail in conjunction with appended drawings, wherein:

FIG. 1 is a front view showing an instrument panel 11 of a vehicle 10 that mounts a mirror switch 100 as a switch device in a preferred embodiment of the present invention;

FIG. 2 is a schematic block diagram showing the switch device in the embodiment of the invention;

FIG. 3 is a longitudinal sectional view of the mirror switch 100 of FIG. 2; and

FIG. 4 is a longitudinal sectional view of the mirror switch of FIG. 2, which is another arrangement example of a control board 200 and a driver board 220.

### DESCRIPTION OF THE PREFERRED EMBODIMENTS

### Embodiment of the Invention

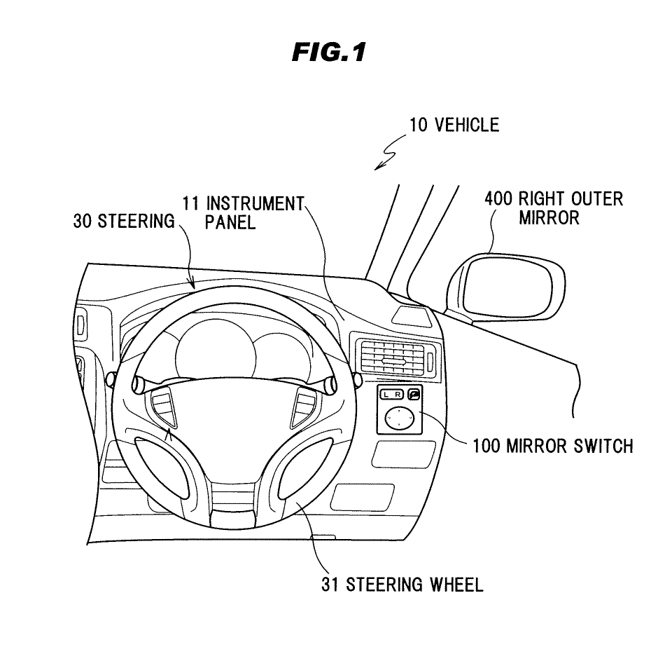

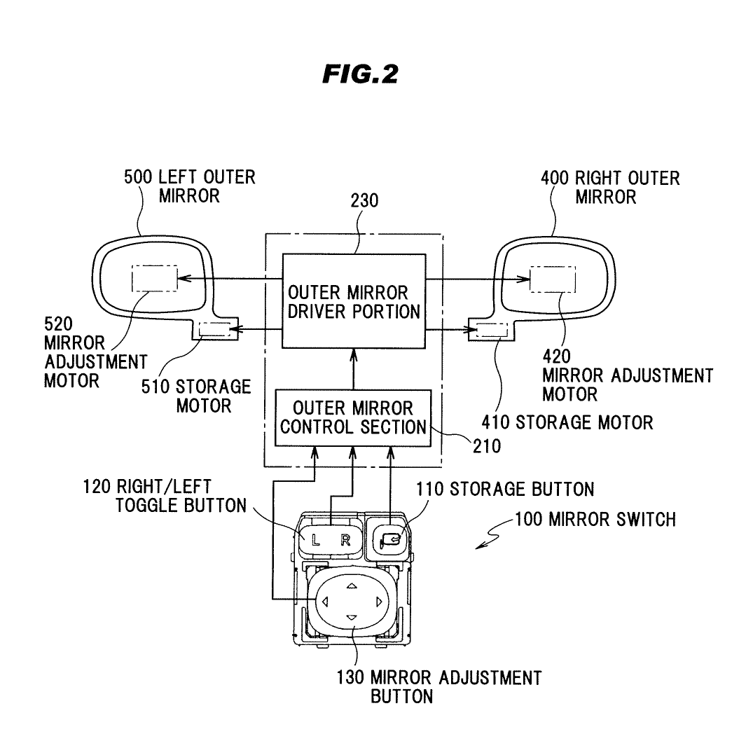

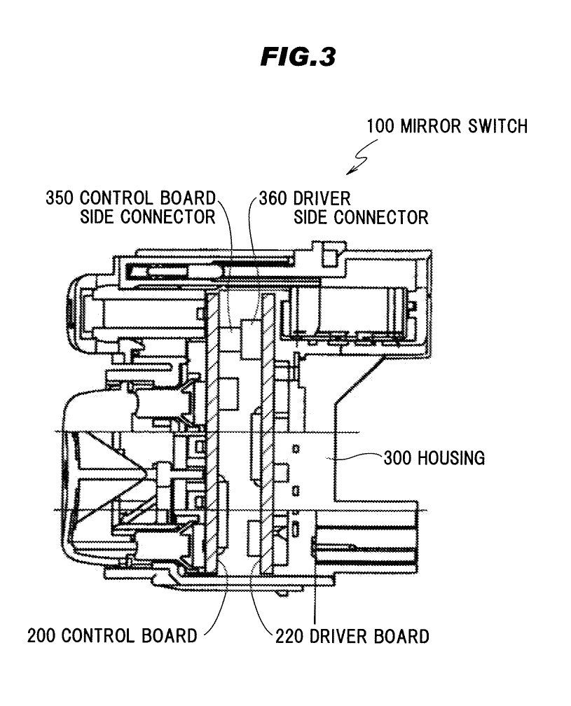

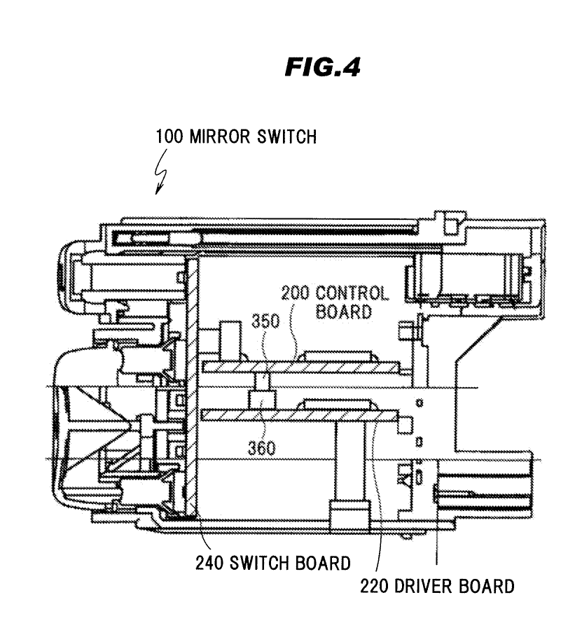

FIG. 1 is a front view showing an instrument panel 11 of a vehicle 10 that mounts a mirror switch 100 as a switch device in an embodiment of the invention. FIG. 2 is a schematic block diagram showing the switch device in the embodiment of the invention. FIG. 3 is a longitudinal sectional view of the mirror switch 100 of FIG. 2. FIG. 4 is a longitudinal sectional view of the mirror switch of FIG. 2, which is another arrangement example of a control board 200 and a driver board 220.

A mirror switch 100 for vehicle outer mirror in the embodiment of the invention is mounted on an instrument panel 11 provided in front of a driver's seat of a vehicle 10, on a right side of a steering 30 and a steering wheel 31. The mirror switch 100 is configured to have a control board 200 that mounts a control element for electrically controlling an outer mirror driver portion, a driver board 220 that mounts a drive element for driving the outer mirror driver portion based on a control signal from the control element, and a housing 300 for housing therein the control board 200 and the driver board 220 that are electrically connected by a coupling means.

FIG. 2 is a schematic block diagram showing the switch device in the embodiment of the invention. A storage button 110, a right/left toggle button 120 and a mirror adjustment button 130 are arranged on a front portion of the mirror switch 100 and are connected so that an operation signal therefrom is input to an outer mirror control section 210. The storage button 110 is an operation button for housing a right outer mirror 400 and a left outer mirror 500 on the vehicle body side and also for opening at the time of driving. The right/left toggle button 120 is a toggle button for selectively operating a right or left outer mirror when adjusting an angle of the outer mirror. In addition, the mirror adjustment button 130 is a joystick-type operation button, which can move the outer mirror selected by the right/left toggle button 120 up, down, right and left, for operating an adjustment direction and an adjustment amount of the mirror.

The outer mirror control section 210 creates a control signal in accordance with a control program, and is connected so as to output the control signal to the outer mirror driver portion 230. The outer mirror driver portion 230 is connected from the inside of the vehicle, i.e., from the inside of the instrument panel 11, via a door portion for driving a storage motor 410 and a mirror adjustment motor 420 of the right outer mirror 400 by performing the required current amplification. Also for the left side, the outer mirror driver portion 230 is connected from the inside of the vehicle, i.e., from the inside of the instrument panel 11, via a door portion for driving a storage motor 510 and a mirror adjustment motor 520 of the right outer mirror 500.

The outer mirror control section 210 has a hardware configuration in which the control board 200 mounts control elements for controlling the outer mirror driver portion such as a microcomputer (CPU) for creating a control signal based on a switch output operated by the storage button 110, the right/left toggle button 120 and the mirror adjustment button 130 on the front portion, a RAM memorizing a control program, and a RAM as a work area, etc.

The outer mirror driver portion 230 drives the storage motor 410 and the mirror adjustment motor 420 of the right outer mirror 400 and the storage motor 510 and the mirror adjustment motor 520 of the left outer mirror 500 based on the control signal from the outer mirror control section 210. Thus, the outer mirror driver portion 230 has a hardware configuration in which the driver board 220 mounts drive elements for driving the outer mirror driver portion such as a driver IC, etc., allowing the required current amplification based on the control signal.

FIG. 3 is a longitudinal sectional view of the mirror switch 100 of FIG. 2. The control board 200 includes a control board side connector 350 and the driver board 220 includes a driver side connector 360. By directly electrically connecting the control board side connector 350 to the driver side connector 360, the control board 200 and the driver board 220 integrally compose an ECU and are housed in the housing 300. Although the control board 200 mounts a microcomputer (CPU), etc., as described above, the control board 200 may mount contact portions of switch elements of the storage button 110, the right/left toggle button 120 and the mirror adjustment button 130 which are arranged on the front portion of the mirror switch 100. According to such a configuration, since the ECU (the control board 200 and the driver board 220) that is necessary for controlling and driving the outer mirror is provided inside the mirror switch 100, it is not necessary to mount a circuit board, etc., inside a door or an instrument panel, thus, it leads to improvement in assembly and reduction of the number of parts management processes, etc.

FIG. 4 is a longitudinal sectional view of the mirror switch in FIG. 2, which corresponds to FIG. 3 and shows another arrangement example of a control board 200 and a driver board 220. Similarly to the embodiment shown in FIG. 3, the control board 200 includes a control board side connector 350 and the driver board 220 includes a driver side connector 360. In the arrangement example shown in FIG. 4, the control board side connector 350 and the driver side connector 360 are directly electrically connected and are arranged in a right and left horizontal position. In such a configuration, a switch board 240 for mounting switch portions of the storage button 110, the right/left toggle button 120 and the mirror adjustment button 130 which are arranged on the front portion of the mirror switch 100 is required, however, regardless of the size of the control board 200 and the driver board 220, it is possible to house the control board 200 and the driver board 220 in the housing 300 within the size of the front portion of the mirror switch 100. It is an effective arrangement when a circuit size of the control board 200 and the driver board 220 is large and a board area is thereby large, or when a size of the front portion of the mirror switch 100 is designed as small as possible, etc.

### Effect of the Embodiment

According to the embodiment of the invention, following effects are obtained.

(1) Since the ECU which is necessary for controlling and driving the outer mirror is configured to be divided into the control board 200 and the driver board 220, a compact mirror switch 100 is possible.
(2) In the same way, since the ECU which is necessary for controlling and driving the outer mirror is configured to be divided into the control board 200 and the driver board 220, it is possible to provide the ECU inside the mirror switch 100 and it is not necessary to mount a circuit board, etc., inside a door or an instrument panel, thus, it leads to improvement in assembly and reduction of the number of parts management processes, etc.
(3) According to a vertical arrangement shown in FIG. 3, it is possible to mount the switch portions of the storage button 110, the right/left toggle button 120 and the mirror adjustment button 130 which are arranged on the front portion of the mirror switch 100, and it is thereby possible to reduce the number of boards.
(4) According to a horizontal arrangement shown in FIG. 4, regardless of the size of the control board 200 and the driver board 220, it is possible to house the control board 200 and the driver board 220 in the housing 300 within the size of the front portion of the mirror switch 100. It is effective when a circuit size of the control board 200 and the driver board 220 is large and a board area is thereby large, or when a size of the front portion of the mirror switch 100 is designed as small as possible, etc.

It should be noted that the present invention is not intended to be limited to the above-mentioned embodiment, and the various kinds of embodiments can be implemented without departing from the gist of the present invention.

Although the invention has been described with respect to the specific embodiment for complete and clear disclosure, the appended claims are not to be therefore limited but are to be construed as embodying all modifications and alternative constructions that may occur to one skilled in the art which fairly fall within the basic teaching herein set forth.

What is claimed is:

1. A switch device for vehicle outer mirror, comprising:
a control board that mounts a control element for electrically controlling an outer mirror driver portion;
a driver board that is separated from the control board and mounts a drive element for driving the outer mirror driver portion based on a control signal from the control board; and
a housing for housing therein the control board and the driver board that are electrically connected by a coupling means.

2. The switch device for vehicle outer mirror according to claim 1, wherein the coupling means is a connector.

3. The switch device for vehicle outer mirror according to claim 1, wherein the control board comprises a contact portion of a switch element for inputting a signal thereto.

4. The switch device for vehicle outer mirror according to claim 1, wherein the housing is arranged on a back side of the switch device.

5. The switch device for vehicle outer mirror according to claim 2, wherein the housing is arranged on a back side of the switch device.

6. The switch device for vehicle outer mirror according to claim 3, wherein the housing is arranged on a back side of the switch device.

7. The switch device for vehicle outer mirror according to claim 1, wherein the control board is arranged substantially parallel to the driver board.

8. The switch device for vehicle outer mirror according to claim 7, wherein the control board and the driver board are arranged substantially parallel to a front face of the switch device.

9. The switch device for vehicle outer mirror according to claim 7, wherein the control board and the driver board are arranged substantially perpendicular to a front face of the switch device.

10. The switch device for vehicle outer mirror according to claim 1, wherein the control board and the driver board compose an ECU that is necessary for controlling and driving an outer mirror.
